(19) United States
(12) Patent Application Publication
(10) Pub. No.: US 2010/0227052 A1
(43) Pub. Date: Sep. 9, 2010

(54) METHODS FOR PROCESSING SUBSTRATES HAVING AN ANTIMICROBIAL COATING

(75) Inventors: Phillip W. Carter, Round Lake, IL (US); John-Bruce D. Green, Buffalo Grove, IL (US)

Correspondence Address: MARSHALL, GERSTEIN & BORUN (BAXTER), 233 SOUTH WACKER DRIVE, 6300 WILLIS TOWER, CHICAGO, IL, 60606-6357, US

(73) Assignees: BAXTER INTERNATIONAL INC., Deerfield, IL (US); BAXTER HEALTHCARE S.A., Zurich (CH)

(21) Appl. No.: 12/400,439

(22) Filed: Mar. 9, 2009

(51) Int. Cl. C23C 16/44; B32B 15/08; B32B 17/10

(52) U.S. Cl. 427/161; 428/458; 428/462; 428/463; 428/339; 427/255.4

(57) ABSTRACT

Methods for processing substrate surfaces carrying coatings comprising a metal are disclosed. The methods involve providing a substrate surface having a coating comprising a metal, and exposing the substrate surface to a halogen-containing gas.

### BACKGROUND

1. Field of the Disclosure

The disclosure relates generally to methods for processing substrates carrying coatings comprising a metal. More particularly, the disclosure is directed to methods of processing substrates, such as medical devices, carrying coatings comprising a metal and having antimicrobial activity.

2. Brief Description of Related Technology

Even brief exposure to surfaces contaminated with microbes can introduce bacterial, viral, fungal, or other undesirable infections to humans and other animals. Of particular concern is preventing or reducing microbial infection associated with the use of invasive medical devices such as catheters, intravenous fluid administration systems, and other medical devices which require prolonged patient contact and thus present significant infection risks. Contamination may result from the patients' own flora or from one or more healthcare workers' hands during insertion and/or manipulation of the device, or from both the patient and the healthcare worker. Medical devices coated with antimicrobial materials can reduce the transfer of such microbes to patients, thereby improving the safety and efficacy of these devices. Such antimicrobial coatings often include silver metal or silver salts, or other metals with demonstrable antimicrobial activity such as copper, gold, zinc, cerium, platinum, palladium, or tin.

Silver and salts thereof are commonly used in antimicrobial coatings because of their demonstrated broad spectrum antimicrobial activity against various bacteria, viruses, yeast, fungi, and protozoa. It is theorized that the observed antimicrobial activity is primarily due to the ability of silver ions to tightly bind nucleophilic functional groups containing sulfur, oxygen or nitrogen. Many nucleophilic functional groups such as thiols, carboxylates, phosphates, alcohols, amines, imidazoles, and indoles are prevalent in biomolecules. Upon binding of ionized silver to these various nucleophilic functional groups, it is believed that widespread disruption and inactivation of microbial biomolecules (and thus antimicrobial activity) occurs.

Silver and salts thereof have therefore been used as antimicrobial agents in a wide variety of applications; for example, they have been incorporated in the absorbent materials of wound care products such as dressings, gels, and bandages, and also in compositions for providing antimicrobial coatings on medical devices. One disadvantage of some metallic silver-containing antimicrobial coatings, however, is their color/opaqueness, which prevents a healthcare provider from being able to see through the medical device substrate. Coatings comprising metallic silver, for example, can be brown in color. Thus, when such colored coatings are applied to transparent surfaces, the coated surfaces typically have a brown color and significantly diminished transparency.

In contrast to coatings comprising metallic silver, many coatings comprising silver salts can be transparent or translucent, and/or lack a colored appearance. Thus, when silver salt coatings are applied to transparent surfaces, the coated surfaces typically have little color and are highly transparent. While coatings comprising silver salts are often translucent, it is extremely difficult to solubilize silver salts and thus to directly deposit coatings comprising silver salts.

### SUMMARY

The present disclosure is directed to methods for processing substrates having or carrying a coating comprising a metal. The methods include providing a substrate surface having a coating comprising a metal, and exposing the substrate surface to a halogen-containing gas. Substrate surfaces having such coatings are typically opaque, as mentioned above. Advantageously, processing such coatings in accordance with the disclosed methods can render the initially opaque coatings substantially translucent.

The substrate surfaces can comprise plastic, glass, metal, ceramics, elastomers, or mixtures or laminates thereof. The substrate surfaces can comprise surfaces of medical devices or medical device components. Preferred examples of substrate surfaces include polycarbonate medical devices. The substrate surface also can comprise surfaces of medical fluid containers or medical fluid flow systems. Preferred examples of medical fluid flow systems include I.V. sets and components thereof, such as, for example, luer access devices.

The metallic coatings can comprise various metals or mixtures of metals. Preferred metals include silver, copper, gold, zinc, cerium, platinum, palladium, and tin. The coatings can comprise metallic nanoparticles.

Suitable halogen-containing gases include various halogens and mixtures of halogens capable of oxidizing metals. Suitable halogen gases include, but are not limited to, fluorine gas; chlorine gas; bromine gas; interhalogen gases, such as chlorine monofluoride (ClF), chlorine trifluoride (ClF₃), chlorine pentafluoride (ClF₅), bromine monofluoride (BrF), bromine trifluoride (BrF₃), bromine pentafluoride (BrF₅), bromine monochloride (BrCl), iodine monofluoride (IF), iodine trifluoride (IF₃), iodine pentafluoride (IF₅), iodine heptafluoride (IF₇), iodine monochloride (ICl), iodine trichloride (ICl₃), and iodine monobromide (IBr); and halogen oxide gases, such as oxygen difluoride, dioxygen difluoride, chlorine oxide, dichloride oxide, chlorine dioxide, dichlorine hexoxide, dichlorine heptoxide, bromine oxide, bromine dioxide, and dibromine oxide.

### DETAILED DESCRIPTION

The present disclosure is directed to methods of processing substrates carrying coatings comprising a metal. The methods according to the invention involve providing a substrate surface carrying a coating comprising a metal and exposing the substrate surface to a halogen-containing gas. In one aspect, the metal can comprise metallic nanoparticles. As used herein, the term “metallic nanoparticles” includes nanoparticles having at least one component (such as, for example, a layer, a core, or a region) comprising a metal. Exemplary metallic nanoparticles include, but are not limited to, silver nanoparticles, silver/silver oxide nanoparticles, gold/silver nanoparticles, copper/copper oxide nanoparticles.

The substrate surfaces carrying coatings comprising a metal can be produced by a wide variety of known methods for coating surfaces with metals. Known techniques for producing such coatings include, for example, silver mirroring, chemical vapor deposition, physical vapor deposition (e.g., sputtering), e-beam deposition, electroplating, and solution coating. Suitable coating compositions for providing a substrate surface carrying a coating comprising a metal and methods for producing such coated substrates are disclosed, for example, in U.S. Pat. Nos. 6,126,931, 6,180,584, 6,264,936, 6,716,895, 7,179,849, 7,232,777, 7,288,264, and U.S. Patent Application Publication Nos. 2007/0003603, and 2007/0207335, the disclosures of which are hereby incorporated by reference in their entireties.

As previously discussed, many coatings comprising a metal are opaque, or exhibit a colored appearance. Thin film coatings comprising metallic silver, for example, can be brown in color, and thus substrates carrying such coatings can have a brown color and exhibit poor transparency. Exposing substrate surfaces carrying coatings comprising a metal to a halogen-containing gas according to the methods disclosed herein can advantageously increase the transparency of the coating comprising a metal, thereby providing, for example, an efficient method for obtaining medical devices comprising a more transparent antimicrobial coating. Accordingly, the disclosed methods advantageously increase the transparency of such coatings and hence the transparency of substrate surfaces carrying such coatings.

In contrast to coatings comprising metals, many coatings comprising metal salts and/or nanoparticles of metal salts are transparent or translucent, and/or lack a colored appearance. Thus, substrates carrying such coatings typically are clear or have a light color, and can be highly transparent. Exposing substrate surfaces carrying coatings comprising a metal to a halogen-containing gas according to the methods disclosed herein is envisioned to form metal salts and/or nanoparticles of metal salts comprising an oxidized form of the metal associated with a halide counteranion. Accordingly, it is believed the disclosed methods can advantageously form metal salts and/or metal salt nanoparticles, thereby increasing the transparency of such coatings and hence the transparency of substrate surfaces carrying such coatings.

Furthermore, when the coatings initially comprise metallic nanoparticles, the disclosed methods can increase the polydispersity of the nanoparticles (in the coatings) and thereby provide coatings capable of broader release profiles and thus of demonstrating sustained antimicrobial activity over time (at least relative to coatings which have not been treated in accordance with the inventive methods). By changing the polydispersity of the coatings initially comprising metallic nanoparticles, the disclosed methods can also provide coatings capable of enhanced efficacy because such coatings include a range of different sized nanoparticles after exposure to a halogen-containing gas in accordance with the disclosure (at least relative to coatings which have not been treated in accordance with the inventive methods) and thus can demonstrate extended/sustained antimicrobial activity (at least relative to coatings which have not been treated in accordance with the inventive methods) because the relatively larger particles are expected to dissolve more slowly relative to the smaller particles contained in the applied coating. Alternatively, the initial coating can comprise nanoparticles having sufficient polydispersity to demonstrate a desired level of extended/sustained antimicrobial activity.

The substrate surfaces of the present disclosure can comprise various materials including, for example, glasses, metals, plastics, ceramics, and elastomers, as well as mixtures and/or laminates thereof. Suitable examples of plastics include, but are not limited to, acrylonitrile butadiene styrenes, polyacrylonitriles, polyamides, polycarbonates, polyesters, polyetheretherketones, polyetherimides, polyethylenes such as high density polyethylenes and low density polyethylenes, polyethylene terephthalates, polylactic acids, polymethyl methyacrylates, polypropylenes, polystyrenes, polyurethanes, poly(vinyl chlorides), polyvinylidene chlorides, polyethers, polysulfones, silicones, and blends and copolymers thereof. Suitable elastomers include, but are not limited to, natural rubbers and synthetic rubbers, such as styrene butadiene rubbers, ethylene propylene diene monomer rubbers (EPDM), polychloroprene rubbers (CR), acrylonitrile butadiene rubbers (NBR), chlorosulphonated polyethylene rubbers (CSM), polyisoprene rubbers, isobutylene-isoprene copolymeric rubbers, chlorinated isobutylene-isoprene copolymeric rubbers, brominated isobutylene-isoprene copolymeric rubbers, and blends and copolymers thereof.

In one preferred embodiment of the present disclosure, the coating comprising a metal is present on (or carried by) a surface of a medical device or medical device component. Medical devices and medical device components which can benefit from the methods according to the disclosure, include, but are not limited to, instruments, apparatuses, implements, machines, contrivances, implants, and components and accessories thereof, intended for use in the diagnosis, cure, mitigation, treatment, or prevention of disease or other condition in humans or other animals, or intended to affect the structure or any function of the body of humans or other animals. Such medical devices are described, for example, in the official National Formulary, the United States Pharmacopoeia, and any supplements thereto. Representative medical devices include, but are not limited to: catheters, such as venous catheters, urinary catheters, Foley catheters, and pain management catheters; dialysis sets; dialysis connectors; stents; abdominal plugs; feeding tubes; indwelling devices; cotton gauzes; wound dressings; contact lenses; lens cases; bandages; sutures; hernia meshes; mesh-based wound coverings; surgical tools; medical monitoring equipment including, but not limited to the touch screen displays often used in conjunction with such equipment; medical pumps; pump housings; gaskets such as silicone O-rings; needles; syringes; surgical sutures; filtration devices; drug reconstitution devices; implants; metal screws; and metal plates. Additional exemplary medical devices include, but are not limited to, medical fluid containers, medical fluid flow systems, infusion pumps, and medical devices such as stethoscopes which regularly come into contact with a patient. One example of a medical fluid flow system is an intravenous fluid administration set, also known as an I.V. set, used for the intravenous administration of fluids to a patient. A typical I.V. set uses plastic tubing to connect a phlebotomized subject to one or more medical fluid sources, such as intravenous solutions or medicament containers. I.V. sets optionally include one or more access devices providing access to the fluid flow path to allow fluid to be added to or withdrawn from the IV tubing. Access devices advantageously eliminate the need to repeatedly phlebotomize the subject and allow for immediate administration of medication or other fluids to the subject, as is well known. Access devices can be designed for use with connecting apparatus employing standard luers, and such devices are commonly referred to as “luer access devices,” “luer-activated devices,” or “LADs.” LADs can be modified with one or more features such as antiseptic indicating devices. Various LADs are illustrated in U.S. Pat. Nos. 5,242,432, 5,360,413, 5,730,418, 5,782,816, 6,039,302, 6,669,681, and 6,682,509, and U.S. Patent Application Publication Nos. 2003/0141477, 2003/0208165, 2008/0021381, and 2008/0021392, the disclosures of which are hereby incorporated by reference in their entireties.

I.V. sets can incorporate additional optional components including, for example, septa, stoppers, stopcocks, connectors, protective connector caps, connector closures, adaptors, clamps, extension sets, filters, and the like. Thus, additional suitable medical devices and medical device components which may be processed in accordance with the methods of the present disclosure include, but are not limited to: I.V. tubing, I.V. fluid bags, I.V. set access devices, septa, stopcocks, I.V. set connectors, I.V. set connector caps, I.V. set connector closures, I.V. set adaptors, clamps, I.V. filters, catheters, needles, stethoscopes, and cannulae. Representative access devices include, but are not limited to: luer access devices including, but not limited to, needleless luer access devices.

The surface of the medical device or medical device component can be fully or partially coated with the coating comprising a metal. The coating can be present on (or carried by) an exterior surface of the device (i.e., a surface which is intended to come into contact with a patient or healthcare provider), an interior surface of the device (i.e., a surface which is not intended to come into contact with a patient or healthcare provider, but which can come into contact with the patient's blood or other fluids), or both. Suitable medical devices and medical device components are illustrated in U.S. Pat. Nos. 4,412,834, 4,417,890, 4,440,207, 4,457,749, 4,485,064, 4,592,920, 4,603,152, 4,738,668, 5,630,804, 5,928,174, 5,948,385, 6,355,858, 6,592,814, 6,605,751, 6,780,332, 6,800,278, 6,849,214, 6,878,757, 6,897,349, 6,921,390, and 6,984,392, and U.S. Patent Application Publication No. 2007/0085036, the disclosures of which are hereby incorporated by reference in their entireties.

The coatings of the present disclosure can comprise metals having antimicrobial properties. Suitable metals for use in the coatings include, but are not limited to: silver, copper, gold, zinc, cerium, platinum, palladium, and tin. Coatings comprising a combination of two or more of the foregoing metals can also be used.

The antimicrobial activity of coatings comprising a metal can be affected by various physical properties of the coatings. When the original coating comprises metallic nanoparticles, the antimicrobial activity can be affected by physical properties such as the average size of the particles, the size distribution of the particles, the arrangement of the particles on the surface, and other factors. Exposing substrate surfaces carrying a coating comprising metallic nanoparticles to a halogen-containing gas according to the methods disclosed herein can alter the physical properties of the nanoparticles, for example, the particle sizes, thereby providing nanoparticle coatings having increased antimicrobial efficacy. As discussed above, the coatings include a range of different sized nanoparticles after exposure to a halogen-containing gas in accordance with the disclosure (at least relative to coatings which have not been treated in accordance with the inventive methods) and thus can demonstrate extended/sustained antimicrobial activity (at least relative to coatings which have not been treated in accordance with the inventive methods) because the relatively larger particles are expected to dissolve more slowly relative to the smaller particles contained in the applied coating.

The antimicrobial activity of coatings comprising a metal can also be affected by various chemical properties of the coatings, such as the incorporation of a halogen in the coatings, the formation of metal salts comprising an oxidized form of the metal associated with a halide counteranion, the composition of additional coating components, and other factors. Exposing substrate surfaces carrying a coating comprising a metal to a halogen-containing gas according to the methods disclosed herein can alter the chemical properties of the coatings, for example, by causing formation of salts, thereby producing coatings having increased antimicrobial efficacy.

When the original coating comprises metallic nanoparticles, the initial diameter of the metallic nanoparticles typically is from about 1 nm to about 1000 nanometers, from about 1 nm to about 100 nanometers, from about 10 nm to about 70 nanometers, and/or from about 30 nm to about 50 nanometers. In this regard, it has generally been found that existing metallic coatings (which have not been treated in accordance with the inventive methods) typically include nanoparticles which have a narrow size distribution (monodisperse), i.e., such coatings comprise nanoparticles of substantially the same diameter. For example, a substantial portion of the nanoparticles in a given coating which has not been treated in accordance with the inventive methods typically have a diameter within ±10 nm of the average diameter, for example, at least 50%, at least 60%, at least 70%, or more of the nanoparticles have a diameter within ±10 nm of the average diameter, for example, at least 50% of the nanoparticles have a diameter between about 30 nm and about 50 nm.

A broad size distribution of metallic nanoparticles often is desirable to modify the rate of release of metal ions from the substrate surface, thereby providing more uniform, sustained release of the metal ions from the coated substrate surface. The methods according to the disclosure typically produce coatings comprising nanoparticles between about 0.1 nm and about 1000 nm, between about 1 nm and about 750 nm, between about 10 nm and about 500 nm, and/or between about 30 nm and about 300 nm, but of course the obtained size range largely depends upon the initial diameter of the metallic nanoparticles. It has generally been found that metallic coating compositions which have been treated in accordance with the inventive methods typically include nanoparticles of varying sizes (i.e., demonstrating polydispersity). For example, typically less than 50% of the nanoparticles in a coating which has been treated in accordance with the inventive methods have a diameter within ±10 nm of the average diameter, for example, less than 40%, less than 30%, less than 20%, or less of the nanoparticles have a diameter within ±10 nm of the average diameter, for example, less than 50% of the nanoparticles have a diameter between about 290 nm and about 310 nm. Coatings comprising nanoparticles demonstrating relatively increased polydispersity are advantageous in that the aforementioned size distribution allows the coatings to advantageously demonstrate a broader release profile over an extended period of time, as explained above.

### Processing Methods

The halogen-containing gases of the present disclosure include a wide variety of known agents for oxidizing metals. Suitable halogen gases include fluorine gas; chlorine gas; bromine gas; interhalogen gases, such as chlorine monofluoride (ClF), chlorine trifluoride (ClF₃), chlorine pentafluoride (ClF₅), bromine monofluoride (BrF), bromine trifluoride (BrF₃), bromine pentafluoride (BrF₅), bromine monochloride (BrCl), iodine monofluoride (IF), iodine trifluoride (IF₃), iodine pentafluoride (IF₅), iodine heptafluoride (IF₇), iodine monochloride (ICl), iodine trichloride (ICl₃), and iodine monobromide (IBr); and halogen oxide gases, such as oxygen difluoride, dioxygen difluoride, chlorine oxide, dichloride oxide, chlorine dioxide, dichlorine hexoxide, dichlorine heptoxide, bromine oxide, bromine dioxide, and dibromine oxide. Mixtures of halogen-containing gases also are included in the disclosed methods. It should be understood that any known halogen-containing gas could be used provided it has a sufficient oxidation potential to at least partially oxidize the metal included in the coating.

Interhalogen gases can be used to obtain multicomponent coatings comprising more than one metal salt. Such multicomponent coatings can demonstrate improved antimicrobial efficacy, improved antimicrobial specificity, and/or improved elution profiles by virtue of including nanoparticles of different salts.

As shown in the examples, coatings comprising bromine salts can have significantly enhanced efficacy relative to other coatings comprising halogen salts. Thus, suitable halogen-containing gases include halogen-containing gases comprising a bromine atom, such as bromine gas and bromine interhalogen gases.

The substrate surfaces of the present disclosure can be exposed to the halogen-containing gas by various known methods. For example, the substrate surface can be exposed to the halogen-containing gas in a sealed vessel. Exposing of the substrate surface to the halogen-containing gas can be carried out at atmospheric pressure or at a pressure below atmospheric pressure. Suitable halogen-containing gas pressures for exposing the substrate include, but are not limited to, about 10⁻⁴ torr to about 7600 torr, about 10⁻³ torr to about 760 torr, about 10⁻² torr to about 10 torr, and/or about 0.1 torr to about 1 torr. The substrate surfaces can be exposed to the halogen-containing gas for various periods of time. The length of desired exposure can be readily determined by one of ordinary skill, and can vary depending on the reactivity of the halogen-containing gas and/or the desired properties of the final coating composition. Typically, the substrate surface is exposed for about 1 second to about 24 hours, but shorter and longer exposure periods can be used. Generally, the substrate surface is exposed to the halogen-containing gas for about 10 seconds to about 2 hours, about 1 minute to about 1 hour, about 5 minutes to about 45 minutes, and/or about 10 minutes to about 30 minutes. The substrate surfaces also can be sequentially exposed to more than one halogen-containing gas, wherein the subsequent halogen-containing gas or gasses can be the same as or different from the first halogen-containing gas. When the second, third, fourth, etc. halogen-containing gas is different from the first halogen-containing gas, multicomponent coatings comprising more than one metal salt can be obtained. Such multicomponent coatings can demonstrate improved antimicrobial efficacy, improved antimicrobial specificity, and/or improved elution profiles by virtue of including nanoparticles of different salts. Short exposure times can be advantageous in producing one or more of the coatings of a multicomponent coating. Short exposure times can also result in incomplete conversion of the metal to metal salts, allowing the remaining unreacted metal to be converted to a (same or different) metal salt in a subsequent coating step.

Halogen-containing gases can be obtained by various known methods. Suitable methods for preparing halogen-containing gases include treating halide salts or hydrogen halides with oxidizing agents, optionally under acidic conditions. For example, bromine gas can be prepared by treating sodium bromide with sodium or potassium persulfate. Similarly, chlorine gas can be prepared by treating hydrogen chloride with hydrogen peroxide in the presence of sulfuric acid. When the halogen is a liquid or solid at standard temperature and pressure (e.g., bromine (I) or iodine(s)), the corresponding halogen-containing gas also can be obtained by subjecting the halogen to reduced pressure, by heating the halogen, or both.

The substrate surfaces can be exposed to the halogen-containing gas at a variety of temperatures. Exposing the substrate surface to the halogen-containing gas can be carried out, for example, at ambient temperature or at an elevated temperature. Suitable temperatures include, but are not limited to, about 25° C. to about 100° C., about 40° C. to about 60° C., and/or about 50° C.

After processing a substrate surface having a coating comprising a metal in accordance with the present methods, the metal content (including metal and metal ions) of the processed coating is typically at least 5% of the metal content of the original coating (prior to processing the substrate surface in accordance with the present methods). Generally, the metal content after processing by exposure to the halogen-containing gas is more than 5% of the metal content prior to exposure. For example, the metal content after exposure can be at least 10%, at least 20%, at least 40%, at least 60%, and/or at least 80% of the metal content prior to processing. After processing a substrate surface having a coating comprising a metal in accordance with the present methods, the coating also can have an increased amount of a halogen, compared to the amount of halogen in the coating prior to processing by exposure to the halogen-containing gas.

The disclosure may be better understood by reference to the following examples which are not intended to be limiting, but rather only set forth exemplary embodiments in accordance with the disclosure.

### EXAMPLES

### Example 1

### Processing of Silver Nanoparticle-Coated Polycarbonate Surfaces with Halogen-Containing Gases

Polycarbonate surfaces having coatings comprising metallic silver nanoparticles were analyzed by transmission electron microscopy (TEM) to determine the initial size range of the silver nanoparticles. First, the silver coating was removed from the polycarbonate surface by rinsing the surface with dichloromethane. The rinse suspension was then centrifuged to separate the silver nanoparticles from the soluble organic components. The supernate was discarded, and the pellet of particles was resuspended in dichloromethane. The suspension was then applied to a carbon film supported on a TEM grid, and the initial size range of the silver nanoparticles was determined by TEM to be about 25 nm to about 50 nm in diameter

Polycarbonate surfaces having an antimicrobial coating comprising silver metallic nanoparticles of about 25 nm to about 50 nm in diameter were exposed to a vapor of chlorine, bromine, or iodine. As controls, one silver-coated polycarbonate surface (Sample 1D) and one uncoated polycarbonate surface (Sample 1E) were not processed according to the methods disclosed herein. The remaining samples (1A-1C) were placed in a glass sublimation reactor with a reservoir containing either solid iodine (Sample 1A), an aqueous solution of 0.2 M NaBr and ˜0.08 M sodium persulfate (Sample 1B), or an aqueous solution comprised of 10 mL of 30 wt % H₂O₂ and 10 niL concentrated H₂SO₄ to which 2 mL conc. HCl was added (Sample 1C). The sublimation reactor was evacuated under house vacuum to generate a vapor of iodine, bromine, or chlorine, according to the composition of the reagents provided in the reservoir. The reactor was heated to 50° C. and the vacuum was held for 15-20 minutes, as indicated in Table 1. The samples were not directly contacted with the solid iodine or aqueous solutions, but rather were contacted with the gases generated by reaction/sublimation of these materials.

After exposure to halogen-containing gases, the initially brown polycarbonate surfaces were rendered light yellow or colorless, as assessed by visual inspection. The transparency of Samples 1A-1E was assessed by transmitted light photography (see Table 1). Transmitted light photographs of the samples were converted to digital grayscale images for analysis. To determine and the intensity of light (I₀) in the absence of the sample, a rectangular area of the image near the sample and representative of the background was selected. Typically, the rectangular area contained approximately 1000 pixels. A histogram displaying a graph of pixel intensity for the selected area was examined, and the mean pixel area was recorded as I₀. To determine and the intensity of light (I) that passed through the sample, a rectangular area of the same size and representative of the sample was selected. A histogram displaying a graph of pixel intensity for the selected area was examined, and the mean pixel area was recorded as I. The relative grayscale value of the sample was defined as: −log(I/I₀). Lower relative grayscale values, therefore, demonstrate that a higher fraction of light is transmitted through the substance. Exposure of the samples to vapors of iodine, bromine, or chlorine produced highly transparent polycarbonate surfaces, as shown in Table 1.

TABLE 1

| | | Reaction Time | Relative |
|---|---|---|---|
| Sample | Conditions | (minutes) | Grayscale Value |
| 1A | Iodine (s) | 20 | 0.33 |
| 1B | NaBr and persulfate | 15 | 0.24 |
| 1C | H₂O₂, H₂SO₄, and HCl | 15 | 0.39 |
| 1D | Untreated coated control | 0 | 1.1 |
| 1E | Uncoated control | 0 | 0.14 |

Energy dispersive x-ray (EDX) spectroscopy was performed on Samples 1A-1E to determine the composition of the coatings after exposure to the halogen-containing gases. As shown by the normalized peak areas in Table 2, essentially no silver was lost from the sample surfaces after exposure to halide gases. As provided in Table 2, the analysis further showed that the appropriate halogen was present on the surfaces for each of the reactive gases (Samples 1A-1C). No halogens were detected for the untreated control samples (Samples 1D and 1E). After exposure to the halogen-containing gas, the particles were found to be larger in size than before, having a mean size of about 300 nm as determined by TEM.

TABLE 2

| | | | | Br/ | |
|---|---|---|---|---|---|
| | | Normalized | I/Ag | Ag | Cl/Ag |
| Sample | Conditions | Ag | ratio | ratio | ratio |
| 1A | Iodine (s) | 0.97 | 0.76 | 0 | 0 |
| 1B | NaBr and persulfate | 0.87 | 0 | 3.14 | 0 |
| 1C | H₂O₂, H₂SO₄, and HCl | 0.78 | 0 | 0.21 | 2.2 |
| 1D | Untreated coated control | 1.0 | 0 | 0 | 0 |
| 1E | Uncoated control | 0 | 0 | 0 | 0 |

The antimicrobial activity of the processed coatings prepared above (Samples 1A-1E) against Staphylococcus aureus (S. aureus) was tested. A suspension of S. aureus was grown in tryptic soy broth for 18-24 hours. The suspension was then diluted in saline to 4.1×10⁵ colony-forming units per mL (cfu/mL). Tubes containing 5 mL saline were inoculated with 0.1 mL (4.1×10⁴ cfu) of the suspension. Samples 1A-1E were aseptically added to the tubes, which were incubated at 20-25° C. for 48 hours. The samples then were plated in tryptic soy agar in triplicate and incubated at 30-35° C. for 48 hours. After this time, growth of S. aureus was measured, as shown in Table 3.

TABLE 3

| | Sample 1 | Sample 2 | Sample 3 | | |
|---|---|---|---|---|---|
| | Recovery | Recovery | Recovery | Average | log |
| Sample | (cfu) | (cfu) | (cfu) | (cfu) | (Average) |
| 1A (iodine | 1.1 × 10¹ | 5.8 × 10¹ | 6.0 × 10² | 2.2 × 10² | 2.34 |
| vapor) | | | | | |
| 1B (bromine | 1.8 × 10⁰ | 0 | 1.8 × 10⁰ | 1.2 × 10⁰ | 0.08 |
| vapor) | | | | | |
| 1C (chlorine | 1.8 × 10¹ | 9.4 × 10¹ | 1.8 × 10¹ | 4.3 × 10¹ | 1.63 |
| vapor) | | | | | |
| 1D | 6.3 × 10¹ | 9.9 × 10¹ | 1.3 × 10¹ | 5.8 × 10¹ | 1.76 |
| (untreated | | | | | |
| coated | | | | | |
| control) | | | | | |
| 1E (uncoated | 2.3 × 10⁴ | 1.8 × 10⁴ | 1.9 × 10⁴ | 2.0 × 10⁴ | 4.30 |
| control) | | | | | |

The silver-coated Samples 1A-1D demonstrated antimicrobial activity against S. aureus, as determined by a comparison of S. aureus recovery from samples 1A-1D relative to S. aureus recovery from a substrate lacking a silver coating (Sample 1E). The silver coatings processed accorded to the disclosed methods (Samples 1A-1C) showed antimicrobial activity comparable to or better than that of an unprocessed silver-coated surface (Sample 1D), in addition to the translucency benefit described above.

### Example 2

### Processing of Silver Nanoparticle-Coated Polycarbonate Surfaces with Halogen-Containing Gases

Polycarbonate surfaces having an antimicrobial coating comprising silver metallic nanoparticles of about 25 nm to about 50 nm in diameter were exposed to a vapor of chlorine, bromine, or iodine. As controls, one silver-coated polycarbonate surface (Sample 2D) and one uncoated polycarbonate surface (Sample 2E) were not processed according to the methods disclosed herein. The remaining samples (2A-2C) were placed in a plastic cylindrical reactor and a stream of the halogen-containing gas was passed through the reactor at atmospheric pressure. Sample 2A was formed by first passing house air through a syringe packed with iodine crystals at room temperature. This air was next passed through a 0.22 micron filter and then directed into the plastic reactor which contained the sample. Sample 2B was formed by first passing house air through a glass Erlenmeyer flask containing ˜0.25 mL of liquid bromine. This air was then directed into the plastic reactor which contained the sample. Sample 2C was formed by directing chlorine gas from a lecture bottle into the plastic reactor, which contained the sample. The samples were held at room temperature and atmospheric pressure in the reactor for 5-30 minutes.

After exposure to halogen-containing gases, the initially brown polycarbonate surfaces were rendered light yellow or colorless, as assessed by visual inspection. The transparency of Samples 2A-2E was assessed as described for Example 1 (see Table 4). Exposure of the samples to vapors of iodine, bromine, or chlorine produced highly transparent polycarbonate surfaces, as shown in Table 4.

TABLE 4

| | | Reaction Time | Relative |
|---|---|---|---|
| Sample | Conditions | (minutes) | Grayscale Value |
| 2A | Iodine (s) with air | 30 | 0.30 |
| 2B | Bromine (l) with air | 10 | 0.17 |
| 2C | Chlorine (g) | 5 | 0.22 |
| 2D | Untreated coated control | 0 | 1.20 |
| 2E | Uncoated control | 0 | 0.10 |

Elemental analysis of Samples 2A-2E by energy dispersive x-ray spectrometry (EDX) showed that essentially no silver was lost from the sample surfaces after exposure to halide gases (see Table 5). As provided in Table 5, the analysis further showed that the appropriate halogen was present on the surfaces for each of the reactive gases (Samples 2A-2C), thereby confirming a change in chemical composition. No halogens were detected for the untreated or uncoated control samples (Samples 2D and 2E).

TABLE 5

| | | | | Br/ | |
|---|---|---|---|---|---|
| | | Normalized | I/Ag | Ag | Cl/Ag |
| Sample | Conditions | Ag | ratio | ratio | ratio |
| 2A | Iodine (s) with air | 1.0 | 0.65 | 0 | 0 |
| 2B | Bromine (l) with air | 1.0 | 0 | 3.5 | 0 |
| 2C | Chlorine (g) | 1.1 | 0 | 0 | 2.0 |
| 2D | Untreated coated control | 1.0 | 0 | 0 | 0 |
| 2E | Uncoated control | 0 | 0 | 0 | 0 |

The antimicrobial activity of the processed coatings prepared above (Samples 2A-2E) against Staphylococcus aureus (S. aureus) was tested. A suspension of S. aureus was grown in tryptic soy broth for 18-24 hours. The suspension was then diluted in phosphate buffered water to 1.6×10⁶ colony-forming units per mL (cfu/5 mL). Samples 2A-2E were aseptically added to the tubes, which were incubated at 20-25° C. for 24 hours. The samples then were plated in tryptic soy agar in triplicate and incubated at 30-35° C. for 48 hours. After this time, growth of S. aureus was measured, as shown in Table 6.

TABLE 6

| | Sample 1 | Sample 2 | | |
|---|---|---|---|---|
| | Recovery | Recovery | Average | log |
| Sample | (cfu) | (cfu) | (cfu) | (Average) |
| 2A (iodine vapor) | 1.7 × 10⁴ | 1.8 × 10³ | 9.4 × 10³ | 4.0 |
| 2B (bromine vapor) | 1.0 × 10² | 1.0 × 10² | 1.0 × 10² | 2.0 |
| 2C (chlorine vapor) | 1.0 × 10² | 2.0 × 10² | 1.5 × 10² | 2.2 |
| 2D (untreated coated | 1.3 × 10⁶ | 1.1 × 10⁴ | 6.6 × 10⁵ | 5.8 |
| control) | | | | |
| 2E (uncoated control) | 5.3 × 10⁷ | 2.6 × 10⁷ | 4.0 × 10⁷ | 7.6 |

The silver-coated Samples 2A-2D demonstrated antimicrobial activity against S. aureus, as determined by a comparison of S. aureus recovery from samples 2A-2D relative to S. aureus recovery from a substrate lacking a silver coating (Sample 2E). The silver coatings processed accorded to the disclosed methods (Samples 2A-2C) showed antimicrobial activity comparable to or better than that of an unprocessed silver-coated surface (Sample 2D), in addition to the translucency benefit described above.

What is claimed is:

1. A method for processing a substrate having a coating comprising a metal comprising: providing a substrate surface having a coating comprising a metal, and exposing the substrate surface to a halogen-containing gas.

2. The method of claim 1, wherein the substrate surface comprises at least one plastic, glass, metal, ceramic, elastomer, or mixtures or laminates thereof.

3. The method of claim 1, wherein the substrate surface comprises a plastic or elastomer selected from the group consisting of: acrylonitrile butadiene styrenes, polyacrylonitriles, polyamides, polycarbonates, polyesters, polyetheretherketones, polyetherimides, polyethylenes, polyethylene terephthalates, polylactic acids, polymethyl methyacrylates, polypropylenes, polystyrenes, polyurethanes, poly(vinyl chlorides), polyvinylidene chlorides, polyethers, polysulfones, silicones, natural rubbers, synthetic rubbers, styrene butadiene rubbers, ethylene propylene diene monomer rubbers, polychloroprene rubbers, acrylonitrile butadiene rubbers, chlorosulphonated polyethylene rubbers, polyisoprene rubbers, isobutylene-isoprene copolymeric rubbers, chlorinated isobutylene-isoprene copolymeric rubbers, brominated isobutylene-isoprene copolymeric rubbers, and blends and copolymers thereof.

4. The method of claim 1, wherein the substrate surface comprises a surface of a medical device or medical device component.

5. The method of claim 1, wherein the substrate surface comprises a surface of a medical fluid container or medical fluid flow system.

6. The method of claim 1, wherein the substrate surface comprises a surface of an I.V. set.

7. The method of claim 1, wherein the substrate surface comprises a surface of a medical device or medical device component selected from the group consisting of: I.V. tubing, I.V. fluid bags, access devices for I.V. sets, septa, stopcocks, I.V. set connectors, I.V. set adaptors, clamps, I.V. filters, catheters, needles, and cannulae.

8. The method of claim 1, wherein the substrate surface comprises a surface of a luer access device or a needleless luer access device.

9. The method of claim 1, wherein the substrate surface comprises an antimicrobial metal coating.

10. The method of claim 1, wherein the metal comprises silver, copper, gold, zinc, cerium, platinum, palladium, tin, or mixtures thereof.

11. The method of claim 1, wherein the metal comprises silver.

12. The method of claim 1, wherein the metal comprises metallic nanoparticles.

13. The method of claim 12, wherein the metallic nanoparticles have an initial diameter of about 1 nm to about 1000 nanometers.

14. The method of claim 1, wherein the exposing occurs for about 1 second to about 24 hours.

15. The method of claim 1, wherein the halogen-containing gas is selected from the group consisting of: fluorine gas, chlorine gas, bromine gas, interhalogen gases, halogen oxide gases, and mixtures thereof.

16. The method of claim 1, wherein the halogen-containing gas is an interhalogen gas or a halogen oxide gas selected from the group consisting of chlorine monofluoride, chlorine trifluoride, chlorine pentafluoride, bromine monofluoride, bromine trifluoride, bromine pentafluoride, bromine monochloride, iodine monofluoride, iodine trifluoride, iodine pentafluoride, iodine heptafluoride, iodine monochloride, iodine trichloride, iodine monobromide, oxygen difluoride, dioxygen difluoride, chlorine oxide, dichloride oxide, chlorine dioxide, dichlorine hexoxide, dichlorine heptoxide, bromine oxide, bromine dioxide, and dibromine oxide.

17. The method of claim 1, wherein the exposing is carried out at a gas pressure of about 10⁻⁴ torr to about 7600 torr.

18. The method of claim 1, wherein the exposing is carried out at a temperature of about 25° C. to about 100° C.

19. The method of claim 1, wherein the coating prior to said exposing has a first metal content, the coating after said exposing has a second metal content, and the second metal content is at least 40% of the first metal content.

20. The method of claim 1, wherein the coating prior to said exposing has a first halide content, the coating after said exposing has a second halide content, and the second halide content is increased compared to the first halide content.

21. The method of claim 1, wherein the substrate surface having the coating comprising a metal is initially opaque and is rendered substantially translucent after exposure to the halogen-containing gas.
